(19) United States
(12) Patent Application Publication
(10) Pub. No.: US 2025/0113569 A1
(43) Pub. Date: Apr. 3, 2025

(54) TRANSISTOR DEVICE

(71) Applicant: Infineon Technologies Austria AG, Villach (AT)

(72) Inventors: Winfried Kaindl, Unterhaching (DE); Christian Fachmann, Villach (AT); Franz Hirler, Isen (DE)

(21) Appl. No.: 18/893,365

(22) Filed: Sep. 23, 2024

(30) Foreign Application Priority Data
Sep. 29, 2023 (DE) 102023126719.1

(51) Int. Cl. H01L 29/10; H01L 21/265; H01L 29/06; H01L 29/417; H01L 29/66; H01L 29/78

(52) U.S. Cl. CPC H10D 62/393; H01L 21/26513; H10D 30/0295; H10D 30/0297; H10D 30/668; H10D 62/111; H10D 62/127; H10D 64/252

(57) ABSTRACT

Disclosed is a transistor device. In an embodiment, the transistor device includes a plurality of transistor cells and a source electrode. Each of the transistor cells includes: a source region of a first doping type; a body region of a second doping type complementary to the first doping type and adjoining the source region; a gate electrode adjacent to the body region, dielectrically insulated from the body region by a gate dielectric, and arranged in a gate trench extending from a first surface of a semiconductor body into the semiconductor body; and a body contact region adjoining the body region and electrically connected to the source electrode. A distance between the body contact region and the gate dielectric is less than 300 nanometers.

### TECHNICAL FIELD

This disclosure relates in general to a transistor device, in particular a superjunction transistor device.

### BACKGROUND

A superjunction transistor device may include a plurality of transistor cells that each include a gate electrode, a source region, a body region adjacent to the gate electrode and dielectrically insulated from the gate electrode by a gate dielectric, and a drift region adjacent to the body region. In an on-state (conducting state) of the transistor device there is a conducting channel in the body region along the gate dielectric. In the off-state, the conducting channel is interrupted. The source region, the adjoining body region, and the drift region form a parasitic bipolar transistor, wherein the body region forms the base of the parasitic transistor.

During operation of the transistor device operating scenarios may occur in which charge carriers are injected into the body region that may cause the parasitic bipolar transistor to switch on, so that the transistor device is in the on-state in an uncontrolled fashion, at least for a certain time period. This is highly undesirable.

### SUMMARY

One example relates to a transistor device. The transistor device includes transistor cells and a source electrode. Each of the transistor cells includes a source region of a first doping type, a body region of a second doping type complementary to the first doping type and adjoining the source region, a gate electrode adjacent to the body region dielectrically insulated from the body region by a gate dielectric and arranged in a gate trench extending from a first surface of a semiconductor body into the semiconductor body. Furthermore, each transistor cell includes a body contact region adjoining the body region and electrically connected to the source electrode. A distance between the body contact region and the gate dielectric is less than 300 nanometers.

Another example relates to a transistor device. The transistor device includes transistor cells and a source electrode. Each of the transistor cells includes a source region of a first doping type, a body region of a second doping type complementary to the first doping type and adjoining the source region, a gate electrode adjacent to the body region dielectrically insulated from the body region by a gate dielectric and arranged in a gate trench extending from a first surface of a semiconductor body into the semiconductor body. Furthermore, each transistor cell includes a body contact region adjoining the body region and electrically connected to the source electrode. The body contact region is connected to the source electrode through an electrically conducting via extending from the source electrode through the insulating layer and a portion of the semiconductor body to the body contact region. A distance between the electrically conducting via and the gate dielectric is less than 350 nanometers.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a vertical cross-sectional view of one portion of a transistor device that includes a plurality of transistor cells;

FIGS. 2 and 3 illustrate horizontal cross-sectional views of the transistor device illustrated in FIG. 1 in different horizontal section planes;

FIGS. 4-7 illustrate detailed views of transistor cells according to different examples;

FIGS. 8A-8C illustrate one example of a method for forming contact regions and contact vias of the transistor cells;

FIGS. 9A-9C illustrate another example of a method for forming contact regions and contact vias of the transistor cells;

FIGS. 10A-10C illustrate yet another example of a method for forming contact regions and contact vias of the transistor cells; and

FIGS. 11A-11B illustrate top views of the transistor device according to different examples.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

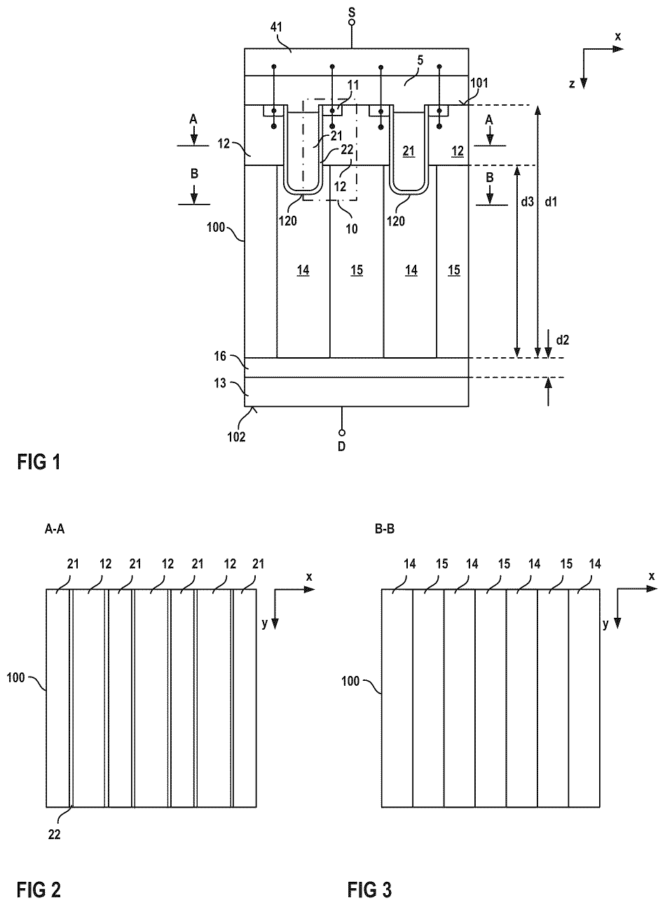

FIG. 1 schematically illustrates one portion of a transistor device that includes a plurality of transistor cells 10. More specifically, FIG. 1 shows a vertical cross-sectional view of one portion of a semiconductor body 100 of the transistor device in which the transistor cells 10 are integrated.

The semiconductor body 100 includes a monocrystalline semiconductor material. The semiconductor material is silicon (Si) or silicon carbide (SiC), for example.

Referring to FIG. 1, each transistor cell 10 includes a source region 11 of a first doping type, a body region 12 of a second doping type complementary to the first doping type, and a gate electrode 21, The gate electrode 21 is adjacent to the body region 12, is dielectrically insulated from the body region 12 by a gate dielectric 22, and is arranged in a gate trench 120 extending from a first surface 101 of the semiconductor body 100 into the semiconductor body 100. Referring to FIG. 1, source and body regions 11, 12 of two neighboring transistor cells may be arranged in a mesa region between neighboring gate trenches 120. In this example, the body regions 12 of the two neighboring transistor cells 10 may be formed by one contiguous doped region of the second doping type. Furthermore, gate electrodes 21 of two (other) neighboring transistor cells may be formed by one contiguous electrode arranged in one gate trench 120.

The gate electrodes 21 include an electrically conducting material. Examples of the electrically conducting material include doped polysilicon, or a metal such as tungsten (W), titanium (Ti), copper (Cu), aluminum (Al), or the like. The gate dielectrics 22 include an oxide, for example. According to one example, the oxide is silicon oxide (SiO₂).

The transistor device further includes a source electrode 41 that is electrically connected to the source and body regions 11, 12 of the transistor cells 10. Connections between the source electrode 41 and the source and body regions 11, 12 are only schematically illustrated in FIG. 1. Detailed examples for connecting the source electrode 41 to the source and body regions 11, 12 are explained herein further below. The source electrode includes an electrically conducting material such as, for example, aluminum (Al), copper (Cu), or an aluminum-copper alloy (AlCu).

The source electrode 41 is separated from the semiconductor body 100 by an insulating layer 5. The insulating layer 5 includes an electrically insulating material such as an oxide, a nitride, or the like.

Referring to FIG. 1, the transistor device further includes a drain region 13 of the first doping type, drift regions 14 of the first doping type, compensation regions 15 of the second doping type, and a buffer region 16. The buffer region 16 is of the first doping type and is arranged between the drain region 13 and the drift and compensation regions 14, 15. The buffer region 16 has a lower doping concentration than the drain region 13 and a higher doping concentration than the drift and compensation regions 14, 15, according to one example.

The transistor device according to FIG. 1 which includes drift regions 14 of the first doping type and compensation regions 15 of the second doping type is a superjunction transistor device.

As explained herein further below, the transistor device can be operated in an on-state or an off-state. In the on-state, they are conducting channel in the body regions 12 along the gate dielectrics between the source regions 11 and the drift regions 14. For this, each of the drift regions 14 adjoins the gate dielectric 22 and the body region 12 of at least one of the transistor cells 10. Each of the compensation regions 15 is adjacent to at least one of the drift regions 15 and is connected to the source electrode 41. In the example illustrated in FIG. 1, each of the compensation regions 15 adjoins the body region 12 of at least one transistor cell and is connected to the source electrode 41 via the respective body region 12.

The transistor device according to FIG. 1 is a vertical transistor device. In this example, the drain region 13 is spaced apart from the source and body regions 11, 12 of the transistor cells 10 in a vertical direction z of the semiconductor body 100. The vertical direction z is essentially perpendicular to the first surface 101. According to one example, the drain region 13 adjoins a second surface 102 opposite the first surface 101 of the semiconductor body 100.

The drain region 13 forms a drain node D or is connected to a drain node D of the transistor device. The source electrode 41 forms a source node S or is connected to a source node S of the transistor device. Furthermore, the gate electrodes 21 are connected to a gate node (not illustrated) of the transistor device.

Referring to FIG. 1, the gate trenches with the gate electrodes 21 are spaced apart from each other in a first lateral direction x of the semiconductor body 100. The first lateral direction x is perpendicular to the vertical direction z. According to one example, the gate electrodes 21 are implemented as stripe electrodes (elongated electrodes). In this example, the gate electrodes 21, in a second lateral direction y perpendicular to the first lateral direction x, are elongated.

One example of elongated gate electrodes 21 is illustrated in FIG. 2, which illustrates one portion of the semiconductor body 100 in a first horizontal section plane A-A cutting through the gate trenches 120 with the gate electrodes 21 and the gate dielectrics 22.

Referring to FIG. 1, the drift regions 14 are spaced apart from each other in the first lateral directions x and a compensation region 15 is arranged between two neighboring drift regions 14.

FIG. 3 illustrates one portion of the semiconductor body 100 in a second horizontal action plane B-B cutting through the drift and compensation regions 14, 15. According to the example illustrated in FIG. 3, the drift regions 14 and the compensation regions 15 are elongated regions having a longitudinal direction that corresponds to the second lateral direction y. In this example, the drift and compensation regions 14, 15 are essentially parallel to the gate trenches 120. This, however, is only an example.

According to another example (not illustrated) longitudinal directions of the drift and compensation regions 14, 15 are perpendicular to the longitudinal directions of the gate trenches 120. In this example, the drift regions 14 are spaced apart from each other in the second longitudinal direction y and are elongated in the first lateral direction x.

The transistor device can be operated in a conventional way by applying a drive voltage (gate-source voltage) between the gate electrodes 21 and the source electrode 41. The transistor device is in the on-state (conducting state) when the drive voltage is such that conducting channels are generated in the body regions 12 along the gate dielectrics 22 between the source regions 11 and the drift regions 14. The transistor device is in the off-state (blocking state) when the electrically conducting channels are interrupted.

The transistor device can be implemented as an N-type transistor device or as a P-type transistor device. An N-type transistor device, for example, is in the on-state, when the drive voltage is higher than a predefined positive threshold voltage and in the off-state, when the drive voltage is below the threshold voltage.

In an N-type transistor device, the doped regions of the first doping type are N-type regions and the doped regions of the second doping type are P-type regions. In a P-type transistor device, the doped regions of the first doping type are P-type regions and the doped regions of the second doping type are N-type regions.

The source regions 11, the body regions 12, the drift and compensation regions 14, 15, the buffer region 16, and the drain region 13 may also be referred to as active device regions. In an N-type transistor device, doping concentrations of the active device regions are selected from the following ranges, for example
Source region 11: 5E19 cm⁻³-5E20 cm⁻³
Body region 12: 3E19 cm⁻³-3E20 cm⁻³
Drain region 13: 5E18 cm⁻³-5E20 cm⁻³
Drift region 14: 7E15 cm⁻³-7E16 cm⁻³
Compensation region 15: 7E15 cm⁻³-7E16 cm⁻³
Buffer region 16: 5E15 cm⁻³-5E16 cm⁻³
Body contact region 17: 1E20 cm⁻³-1E21 cm⁻³

The transistor device can be operated in a forward operating mode or in a reverse operating mode. The transistor device is in the forward operating mode when a voltage is applied between the drain node D and the source node S that reverse biases PN junctions between the drift regions 14 and the body regions 12. An N-type transistor device, for example, is in the forward operating mode when a positive voltage is applied between the drain node D and the source node S and in the reverse operating mode when a negative voltage is applied between the drain node D and the source node S.

When the transistor device is in the on-state and the forward operating mode, first type charge carriers flow from the drain source regions 11 via the conducting channels along the gate dielectrics 22, the drift regions 14, and the buffer region 16 to the drain region 13. In an N-type transistor device, for example, the first type charge carriers are electrons.

When the transistor device is in the off-state and the forward operating mode, the conducting channels along the gate dielectrics 22 are interrupted and the PN junctions between the body regions 12 and the drift regions 14 are reverse biased. In this operating mode, a charge carrier flow between the source regions 11 and the drain region 13 is interrupted as long as a voltage applied between the drain and source nodes D, S is lower than a voltage blocking capability of the transistor device. When the voltage applied between the drain and source nodes D, S is higher than the voltage blocking capability an Avalanche breakdown may occur resulting in Avalanche current flowing between the source regions 11 and the drain regions 13. An operating mode of the transistor device in which an Avalanche current flows is referred to as Avalanche mode in the following.

In the reverse operating mode, the PN junctions between the drift regions 14 and the body regions 12 are forward biased, so that the transistor device conducts independent of whether or not a conducting channels are generated along the gate dielectrics 22 by applying a suitable drive voltage. An N-type transistor device, for example, is in the reverse operating mode when a positive voltage is applied between the source node S and the drain node D.

When the transistor device is in the on-state (so that there are conducting channels along the gate dielectrics 22) and the reverse operating mode, a current flowing between the source and drain regions 12, 13 is essentially a unipolar current. A unipolar current is a current that essentially only includes majority charge carriers, which are charge carriers of the first type.

When the transistor device is in the off-state (so that conducting channels along the gate dielectrics 22 are interrupted), the current flowing between the source and drain regions 12, 13 is a bipolar current. A bipolar current includes charge carriers of the first type and charge carriers of the second type. In an N-type transistor device, first type charge carriers are electrons and second type charge carriers are holes. The operating mode of the transistor device in which a bipolar current flows is referred to as a diode mode in the following. The second type charge carriers are minority charge carriers in the transistor device.

In each transistor cell 10, the source region 11, the body region 12 and the drift region 14 adjoining the body region 12 form a parasitic bipolar transistor. Especially when the transistor device is in the Avalanche mode or when the transistor device is in the diode mode second type charge carriers may be injected into the body regions 12. These charge carriers may cause the parasitic bipolar transistor to switch on. This is highly undesirable as this would render the transistor device to conduct in an uncontrolled fashion.

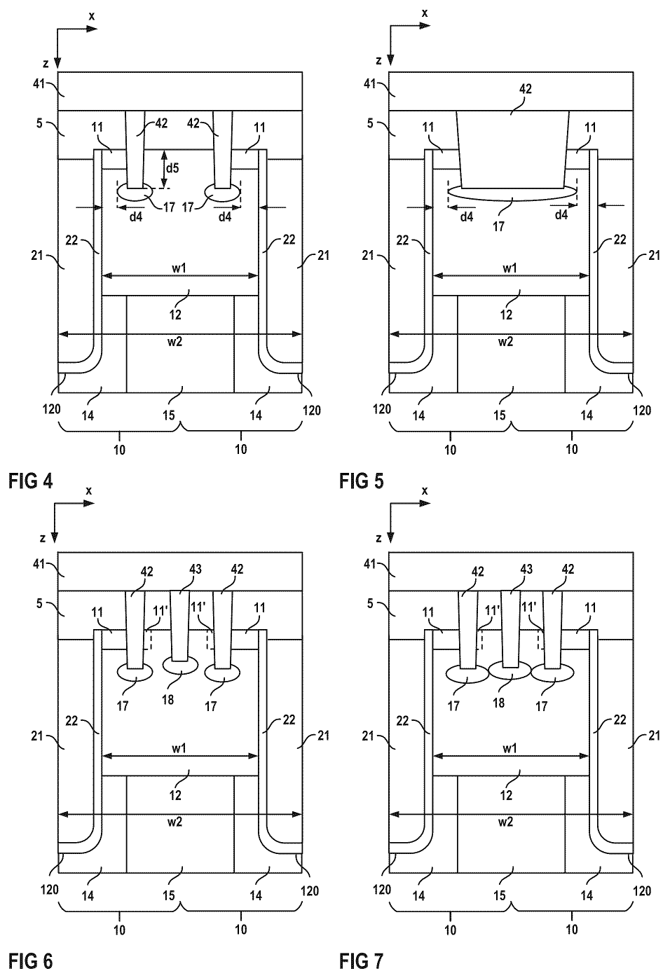

FIGS. 4-7 illustrates different examples for implementing the transistor device in such a way that the risk of switching on the parasitic bipolar transistor is significantly reduced. Each of FIGS. 4-7 shows a vertical cross-sectional view of one portion of the semiconductor body 100 that includes two neighboring transistor cells 10. More specifically, each of FIGS. 4-7 illustrates one mesa region between two neighboring gate trenches 120, portions of the neighboring gate trenches 120 with the gate electrodes 21 and the gate dielectrics 22, and portions of the drift and compensation regions 14, 15 adjoining the body region 12 of the two transistor cells 10.

Referring to FIGS. 4-7, each of the transistor cells 10 includes a body contact region 17 of the second doping type that is electrically connected to the source electrode 41 through an electrically conducting via 42. The body contact region 17 adjoins the body region 12, so that the body region 12 is electrically connected to the source electrode 41 via the body contact region 17 and the electrically conducting via 42. A doping concentration of the body contact region 17 is higher than a doping concentration of the body region 12 and high enough to achieve and make contact between the electrically conducting via 42 and the body contact region 17.

The electrically conducting via 42 includes an electrically conducting material such as tungsten (W), titanium (Ti), or the like.

The via 42 is also connected to the source region 11 of the respective transistor cell 10, so that the source region 11 is connected to the source electrode 41 through the electrically conducting via 42.

In each transistor cell 10, the body contact region 17 not only serves to connect the body region 12 to the via 42 and the source electrode 41, but also serves to collect second type charge carriers that may be injected into the body region 12, so as to prevent those second type charge carriers from switching on the parasitic bipolar transistor. In order to achieve a high efficiency of the body contact region 17 in collecting the minority charge carriers, the body contact region 17 is arranged close to the respective gate dielectric 22. This includes that a distance d4 (see FIGS. 4 and 5) between the body contact region 17 and the respective gate dielectric 22 is less than 300 nanometers.

According to one example, the distance d4 between the body contact region 17 and the respective gate dielectric 22 is greater than 150 nanometers.

Arranging the body contact region 17 close to the gate dielectric 22 prevents minority charge carriers from moving to the source region 11 along the gate dielectric 22. Minority charge carriers moving along the gate dielectric 22 to the source region 11 may cause a voltage drop that may cause the parasitic bipolar transistor to switch on. Thus, collecting these minority charge carriers by the body contact region 17 may help to prevent the parasitic bipolar transistor from switching on.

Referring to FIGS. 4-7, the body contact regions 17 may be spaced apart from the source regions 11 in the vertical direction z. This, however, is only an example. According to another example (not illustrated) the body contact region 17 of one transistor cell 10 adjoins both the body region 12 and the source region 11 of the respective transistor cell 10.

According to one example illustrated in FIG. 4, the two transistor cells 10 that have their body and source regions 11, 12 arranged in a common mesa region between two neighboring gate trenches 120 each include a body contact region 17 and a respective via 42, wherein the two body contact regions 17 and the vias 42 are spaced apart from each other in the first lateral direction x.

According to another example illustrated in FIG. 5, the two transistor cells 10 that have their body and source regions 11, 12 arranged in a common mesa region between two neighboring gate trenches 120 share a body contact region 17 and a respective via 42.

Referring to FIGS. 4-7, the source regions 11 of the two neighboring transistor cells 10 that share the mesa region are spaced apart from each other in the first lateral direction x. In the example illustrated in FIG. 4 in which each of the transistor cells 10 has its own body contact region 17 and the respective via 42, each of the source regions 11 may be implemented such that, in a direction facing away from the respective gate dielectric 22, it does not extend beyond the via 42, so that the source region 11, in the first lateral direction x, is only arranged between the gate dielectric 22 and the via 42.

The source regions 11 may be formed before forming the gate vias 42. Due to unavoidable variances in the dimension of the source regions 11 in the first lateral direction x and the positioning of the vias 42 relative to the source regions 11 the source region may be subdivided by the respective via 42 into the desired source region 11 arranged between the gate dielectric 22 and the via 42 and a residual 11′ separated from the source region 11 by the via 42. Such optional residuals 11′ are illustrated in dashed lines in FIGS. 6 and 7.

Each of the residuals 11′ forms a parasitic bipolar transistor together with the body region 12 and a drift region 14. In order to ensure that parasitic bipolar transistors formed by the residuals 11′, the body regions 12 and the drift regions 14 do not negatively affect operation of the transistor device, at least one further body contact region 18 may be arranged in the mesa region between 2 neighboring body contact regions 17, wherein the further body contact region 18 is connected to the source electrode 41 through a respective electrically conducting via 43.

As illustrated in FIG. 6, the further body contact region 18 may be spaced apart from the body contact regions 17 in the first lateral direction x. According to one example, distances between the further body contact region 18 and the body contact regions 17 are less than 300 nm, in particular less than 200 nm or less than 100 nm.

According to another example illustrated in FIG. 7, the further body contact region 18 adjoins the body contact regions 17. In this example, the vias 42, the body contact regions 17, and the further body contact region 18 form a closed shield around the residuals 11′.

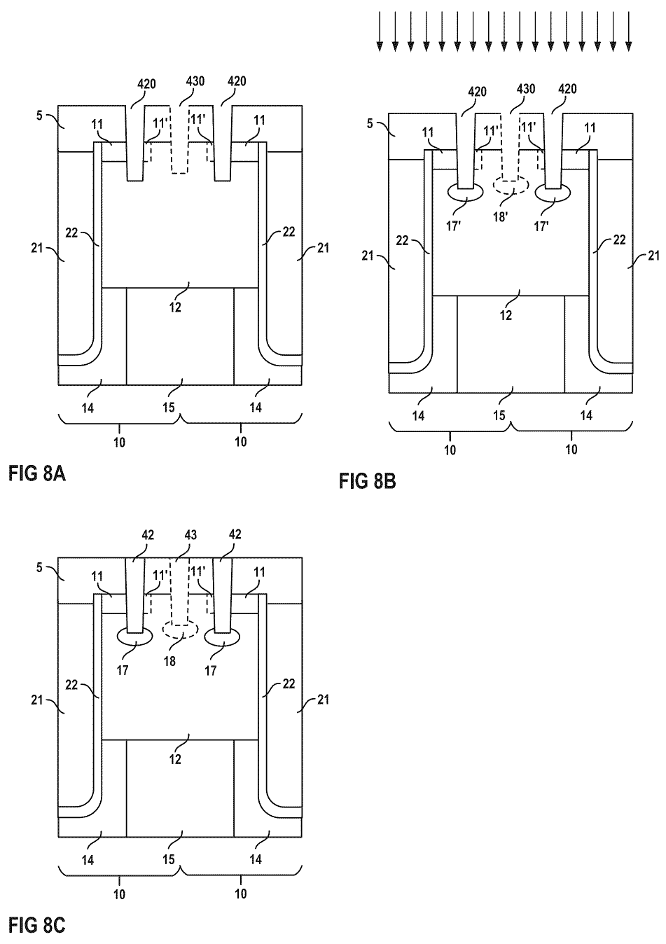

FIGS. 8A-8C illustrate one example of a method for forming the body contact regions 17 and the electrically conducting vias 42 of arrangements according to FIGS. 4, 6, and 7.

In the example illustrated in FIGS. 8A-8C, the body contact regions 17 and the vias 42 are formed after forming the gate electrodes 21 and the gate dielectrics 22 in the gate trenches 120, the source and body regions 11, 12 in the mesa regions, and the insulating layer 5 above the gate electrodes 21 and the first surface 101 of the semiconductor body 100. Referring to FIG. 8A, the method includes forming contact trenches 420 that extend through the insulating layer 5 into the mesa region with the source and body regions 11, 12. The contact trenches 420 are formed such that each of the contact trenches 420 adjoins the source region 11 of the respective transistor cell 10 and, in the vertical direction, extends into the body region 12. forming the contact trenches 420 may include a conventional etching process using an etch mask (not illustrated) formed on top of the insulating layer 5.

Referring to FIG. 8B, the method further includes implanting second type dopant atoms via bottoms of the contact trenches 420 into the body region 12 to form implanted regions 17′. Based on the implanted regions 17′ the body contact regions 17 are formed in an annealing process. This annealing process may take place directly after the implantation and before forming the vias 42, or may take place after forming the vias 42.

It should be noted that forming the source and body regions 11, 12 may also include an implantation process to implant dopant atoms into the semiconductor body and a subsequent annealing process. The same annealing process may be used to form the source and body regions 11, 12 and the body contact regions 17. According to another example, different annealing processes are used to form the source and body regions 11, 12 on one side and the body contact regions 17 on the other side.

Referring to FIG. 8C, the method further includes forming the vias 42 in the contact trenches 420. Forming the vias 42 may include completely filling the contact trenches with an electrically conducting material. Alternatively, forming the vias 42 includes lining bottoms and sidewalls of the contact trenches 420 with an electrically conducting material.

The optional further body contact region 18 and the corresponding via 43 may be formed by the same process sequence that forms the body contact regions 17 and the corresponding vias 42. Forming the optional further body contact region 18 and the corresponding via 43 is illustrated in dashed lines in FIGS. 8A-8C. This process includes forming a further contact opening 430 together with the contact openings 420 (see FIG. 8A), implanting second type dopant atoms into the further contact opening 430 to form a further implanted region 18′, forming the further body contact region 18 based on the further implanted region 18′ using an annealing process, and forming the further via 43 in the further contact opening 430.

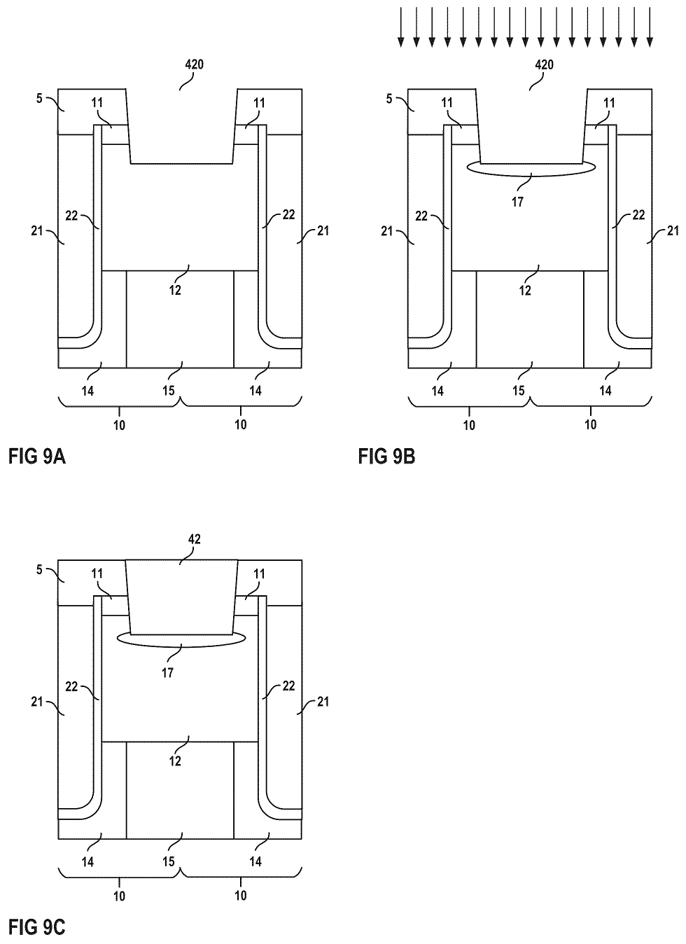

FIGS. 9A-9C illustrates one example of a method for forming an arrangement of the type illustrated in FIG. 5 in which the two neighboring transistor cells 10 share the body contact region 17 and the corresponding via 42. The method according to FIGS. 9A-9C is based on the method according to FIGS. 8A-8C and is different from the method according to FIGS. 8A-8C in that only one contact opening 420 is formed (see FIG. 9A), dopant atoms are implanted into the one contact opening 422 to form one implanted region 17′ (see FIG. 9B), only one body contact region 17 is formed in each mesa region based on the implanted region 17′, and the via 42 is formed in the contact opening 420.

In each of the examples illustrated in FIGS. 8A-8C and 9A-9C, in the implantation process for forming the implanted regions 17′, the implantation energy is selected such that the dopant atoms are implanted in a region close to the bottom of the contact opening 420, so that the resulting body contact region 17 adjoins the bottom and is connected to the via 42 formed in the contact opening 420. According to one example, the implantation energy is selected from between 10 keV and 50 keV. According to one example, the implantation dose is selected from between 5E14 cm⁻² and 5E15 cm⁻².

According to one example, the implantation dose is selected such that the minimum doping concentration of the body contact region 17 is at least 10 times the doping concentration of the body region 12.

Furthermore, the thickness of the insulating layer 5 is adapted to the implantation energy such that dopant atoms are not implanted through the insulating layer 5 into the semiconductor body 100.

Referring to the above, forming the body contact regions 17 based on the implanted regions 17′ includes an annealing process. According to one example, a temperature and duration of this annealing process is selected such that the implanted dopant atoms are electrically activated. As can be seen from the drawings, the body contact regions 17, to a certain extent, may extend from the via 42 to the gate dielectric 22. This may be due to a diffusion in the annealing process but may also be due to straggling in the implantation process. A dedicated annealing process may be used to activate the dopant atoms included in the body contact regions 17. According to another example, an annealing process that is used for activating the dopant atoms in the source and body regions 11, 12, for example, is used to activate the dopant atoms included in the body contact regions 17.

Referring to the above, the body contact regions 17 are spaced apart from the gate dielectric 22 less than 300 nm. The contact openings (contact trenches) 420 are formed to be spaced apart from the gate dielectric 22 less than 350 nm or less than 300 nm, for example.

According to one example, the vertical dimension of the contact openings 420 in the semiconductor body 100 is between 400 nm and 600 nm. The vertical dimension is the dimension of the contact openings 420 in the vertical direction z. That is, in this example, the contact openings 420 extend through the insulating layer 5 and extend between 400 nm and 600 nm from the first surface 101 into the semiconductor body 100. The vertical dimension of the source regions 11 is between 100 nm and 200 nm, for example. Thus, the body contact regions 17, that are formed by implanting dopant atoms into the bottoms of the contact openings 420, may be spaced apart from the source regions 11.

The depth of the gate trenches 120, which is the dimension of the gate trenches 120 in the vertical direction z, is between 2 micrometers and 4 micrometers, for example. The width of the gate trenches 120, which is the dimension of the gate trenches 120 in the first lateral direction x, is between 700 nm and 1.3 micrometers (1300 nm), for example. A pitch w2 (see FIGS. 4-7), which is a center-to-center distance between two neighboring gate trenches is between 3 micrometers and 5 micrometers, for example. The lateral dimension w1 of the mesa region is given by the pitch w2 minus the gate trench width.

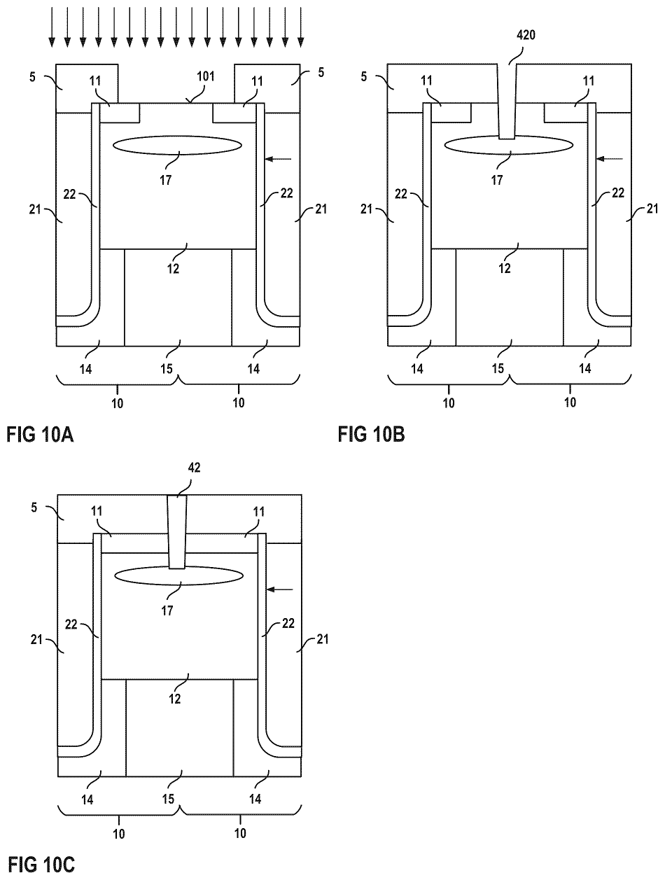

FIGS. 10A-10C illustrate another example of a method for forming a common body contact region 17 and a corresponding via 42.

Referring to FIGS. 10A-10B, this method includes forming an implanted regions 17′ by implanting second type dopant atoms via the first surface 101 into the body region 12. The dopant atoms are implanted using an implantation mask 301 that includes an opening, wherein the opening defines those regions into which dopant atoms are to be implanted. The source and body regions 11, 12 may be formed before or after implanting the dopant atoms to form the implanted region 17′. The implantation process takes place before forming the insulating layer 5 on top of the first surface 101 of the semiconductor body 100.

Referring to FIG. 10B, the method further includes forming the insulating layer 5 and forming the contact opening 420 in the insulating layer 5 and in portions of the semiconductor body 100. The contact opening (contact trench) 420 is formed such that it extends through the insulating layer 5 and portions of the semiconductor body 100 into the implanted region 17′ or the body contact region 17.

As explained above, forming the body contact region 17 based on the implanted region 17′ includes an annealing process. This annealing process may take place before or after forming the contact opening 420. Consequently, the contact opening 420 is formed to either extend into the implanted region 17′ or into the body contact region 17.

Referring to FIG. 10C, the method further includes forming the contact via 42 in the contact opening 420. In the example illustrated in FIG. 10C, the source regions 11, in lateral directions, extend to the contact via 42. This, however, is only an example. According to another example (not illustrated) the transistor device includes further contact vias that connect the source regions 11 to the source electrode 41 (not illustrated in FIG. 10C).

In each of the examples explained herein before, the source electrode 41 is formed on top of the insulating layer 5 after forming the contact vias 42 and the optional further contact vias 43.

Referring to the above, the body contact regions 17 increase the robustness of the transistor device, in particular the robustness of the transistor device in the Avalanche mode or the diode mode. The buffer region 16 also contributes to the robustness of the transistor device in this operating modes. Referring to the above, the buffer region 16 is arranged between the drift regions 14 and the drain region 13 and has a lower doping concentration than the drift regions 14 and the drain regions 13. The buffer region 16 contributes to the on-resistance of the transistor device, which is the electrical resistance between the drain and source nodes D, S in the on-state. Basically, the higher the thickness of the buffer region 16 the higher the on-resistance.

In the transistor device explained herein before, which includes the body contact regions 17 close to the gate dielectric 22 In order to deactivate the parasitic bipolar transistor a thickness of the buffer region 16 can be reduced as compared to a conventional superjunction transistor device.

The thickness d2 (see FIG. 1) of the buffer region 16 is the dimension of the buffer region 16 in the vertical direction z of the semiconductor body 100. According to one example, the thickness d2 of the buffer region 16 is less than 25% or even less than 20% of a distance dl between the buffer region 16 and the first surface 101.

According to one example, the thickness d2 and the doping concentration of the buffer region 16 are adapted to one another in such a way that a portion of an overall on-resistance of the transistor device that results from the electrical resistance of the buffer region 16 is between 10% and 20% of the overall on-resistance.

The distance between the buffer region 16 and the first surface 101 is mainly given by the vertical dimension d3 of the drift and compensation regions 14, 15. The doping of the drift and compensation regions 15 and the vertical dimension d3 of the drift and compensation regions 14, 15 mainly define the voltage blocking capability of the transistor device. The vertical dimension of the body region 12 is much lower than the vertical dimension of the drift and compensation regions 14, 15 and is less than 3% or even less than 2% of the vertical dimension d3 of the drift and compensation regions 14, 15.

According to one example, the distance dl between the buffer region 16 and the first surface 101 is between 35 micrometers and 50 micrometers.

According to one example, the voltage blocking capability of the transistor device is 600 V. In this example, the distance between the buffer region 16 and the first surface 101 is between 38 micrometers and 42 micrometers, and the thickness d3 of the buffer region 16 is between 6 micrometers (μm) and 10 micrometers, for example.

According to another example, the voltage blocking capability of the transistor device is 650V. In this example, the distance between the buffer region 16 and the first surface 101 is between 42 micrometers and 44 micrometers, and the thickness d3 of the buffer region 16 is between 8 micrometers and 11 micrometers, for example.

In both examples, the vertical dimension of the body region 12 is between 800 nanometers (nm) and 1.8 micrometers, for example.

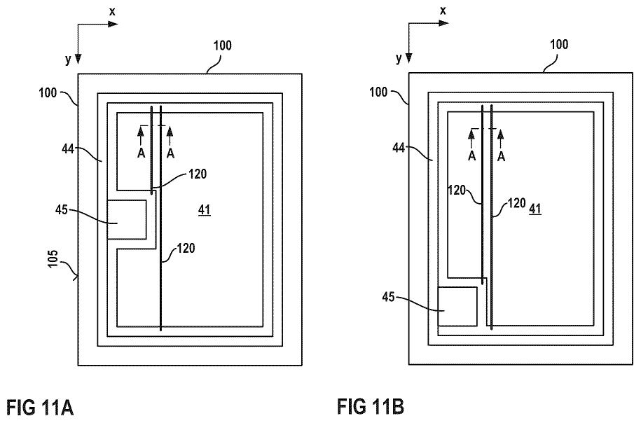

FIGS. 11A-11B schematically illustrate top views of the overall transistor device according to two different examples. More specifically, FIGS. 11A-11B show a top view of the source electrode 41 and further features formed above the first surface 101 (out of view in FIGS. 11A-11B) of the semiconductor body 100.

Referring to FIGS. 11A-11B, each of the transistor devices includes a gate runner 44 and a gate pad 45 connected to the gate runner 44. The gate runner 44, in horizontal directions surrounds the source electrode 41. The gate pad 45 and the gate runner 44 are spaced apart from the source electrode 41. The gate pad 45, the gate runner 44, and the source electrode 41 may include the same material and may be formed by the same process. The gate pad 45 may adjoin the gate runner 41 (as illustrated). According to another example (not illustrated) the gate pad 45 is spaced apart from the gate runner 44 and a resistor (gate resistor) is formed between the gate runner 44 and the gate pad 45.

The transistor cells 10 are out of view in FIGS. 11A and 11B. Just for the purpose of illustration, the position of two of the plurality of gate trenches 120 relative to the source electrode 41 and the gate runner 44 are illustrated by bold lines in FIGS. 11A-11B. As explained above, in each of these gate trenches 120 a respective electrode is arranged that forms the gate electrode of at least one transistor cell 10. The gate electrode 21 in each of these trenches is electrically connected to the gate runner 44 at at least one of two opposing longitudinal ends of the respective gate electrode 21. The longitudinal ends of the gate electrodes 21 are ends of the gate electrodes 21 in the second lateral direction y. The gate electrodes 21 are connected to the gate runner 44 in a conventional way, using electrically conducting vias, for example. Such connections, however, are not illustrated in FIGS. 11A-11B.

The gate pad 45 forms the gate node of the transistor devices, so that the drive voltage for switching on or switching of the transistor cells 10 may be applied between the gate pad 45 and the source electrode 41, which may also be referred to as source pad.

In the example illustrated in FIG. 11A, the gate pad 45 is arranged at a position that is essentially in the middle between two opposing sidewalls of the semiconductor body 100. In the example according to FIG. 11B, the gate pad 45 is arranged at a position that is close to a corner formed by two adjacent sidewalls of the semiconductor body 100. In each of these examples, the transistor device may include two types of gate electrodes 21, gate electrodes of a first type and gate electrodes of a second type. First type gate electrodes 21 have both a first longitudinal end and an opposing second longitudinal and 122 connected to the gate runner 44. Second type gate electrodes only have one longitudinal end connected to the gate runner 44.

The semiconductor body 100 may include an inner region and an edge region. The inner region, which may also be referred to as active region, includes the transistor cells 10 and is essentially that region of the semiconductor body 100 arranged below the source electrode 41. The edge region is arranged between the inner region and the sidewalls of the semiconductor body 100. According to one example, the gate runner 44 and the gate pad 45 are arranged above the edge region of the semiconductor body 100.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device, comprising:
a plurality of transistor cells; and
a source electrode, wherein each of the transistor cells comprises:
a source region of a first doping type;
a body region of a second doping type complementary to the first doping type and adjoining the source region;
a gate electrode adjacent to the body region, dielectrically insulated from the body region by a gate dielectric, and arranged in a gate trench extending from a first surface of a semiconductor body into the semiconductor body;
a body contact region adjoining the body region and electrically connected to the source electrode,
wherein a distance between the body contact region and the gate dielectric is less than 300 nanometers.

2. The transistor device of claim 1, wherein the distance between the body contact region and the gate dielectric is greater than 150 nanometers.

3. The transistor device of claim 1, further comprising:
an insulating layer arranged between the source electrode and the first surface of the semiconductor body.

4. The transistor device of claim 3, wherein the body contact region is connected to the source electrode through an electrically conducting via extending from the source electrode through the insulating layer and a portion of the semiconductor body to the body contact region.

5. The transistor device of claim 4, wherein a distance between the electrically conducting via and the gate dielectric is less than 350 nanometers.

6. The transistor device of claim 5, wherein source and body regions of two neighboring transistor cells are arranged in a mesa region between neighboring gate trenches, and wherein each of the two neighboring transistor cells comprises a respective body contact region and a respective electrically conducting via.

7. The transistor device of claim 5, wherein source and body regions of two neighboring transistor cells are arranged in a mesa region between neighboring gate trenches, and wherein the two neighboring transistor cells comprises a common body contact region and a common electrically conducting via connected between the body contact region and the source electrode.

8. The transistor device of claim 6, further comprising:
a further body contact region arranged between the body contact regions of the neighboring transistor cells and connected to the source electrode through a further electrically conducting via.

9. The transistor device of claim 8, wherein the further body contact region is spaced apart from the body contact regions of the neighboring transistor cells.

10. The transistor device of claim 8, wherein the further body contact region adjoins the body contact regions of the neighboring transistor cells.

11. The transistor device of claim 1, wherein a doping concentration of the body contact region is at least 10 times a doping concentration of the body region.

12. The transistor device of claim 1, further comprising:
drift regions of the first doping type;
compensation regions of the second doping type;
a drain region of the first doping type; and
a buffer region of the first doping type arranged between the drain region and the drift and compensation regions,
wherein each of the drift regions adjoins the body region of at least one of the transistor cells, and
wherein each of the compensation regions is connected to the source electrode and is adjacent to at least one of the drift regions.

13. The transistor device of claim 12, wherein each of the compensation regions adjoins the body region of at least one of the transistor cells.

14. The transistor device of claim 12, wherein a dimension of the buffer region in a vertical direction of the semiconductor body is less than 25% of a distance between the buffer region and the first surface.

15. The transistor device of claim 14, wherein the distance between the buffer region and the first surface is between 35 micrometers and 50 micrometers.

16. A transistor device, comprising:
a plurality of transistor cells; and
a source electrode,
wherein each of the transistor cells comprises:
a source region of a first doping type;
a body region of a second doping type complementary to the first doping type and adjoining the source region;
a gate electrode adjacent to the body region, dielectrically insulated from the body region by a gate dielectric, and arranged in a gate trench extending from a first surface of a semiconductor body into the semiconductor body;
a body contact region adjoining the body region and electrically connected to the source electrode,
wherein the body contact region is connected to the source electrode through an electrically conducting via extending from the source electrode through the insulating layer and a portion of the semiconductor body to the body contact region,
wherein a distance between the electrically conducting via and the gate dielectric is less than 350 nanometers.

17. The transistor device of claim 16, wherein the distance between the electrically conducting via and the gate dielectric is less than 300 nanometers.
